(19) United States
(12) Patent Application Publication
(10) Pub. No.: US 2022/0130969 A1
(43) Pub. Date: Apr. 28, 2022

(54) POWER DEVICE WITH A CONTACT HOLE ON A SLOPED ILD REGION

(71) Applicant: SEMICONDUCTOR COMPONENTS INDUSTRIES, LLC, Phoenix, AZ (US)

(72) Inventors: Reiki FUJIMORI, Aizuwakamatsu (JP); Takashi HIROSHIMA, Ota-City (JP)

(73) Assignee: SEMICONDUCTOR COMPONENTS INDUSTRIES, LLC, Phoenix, AZ (US)

(21) Appl. No.: 16/949,272

(22) Filed: Oct. 22, 2020

(51) Int. Cl. H01L 29/417; H01L 29/423; H01L 29/66; H01L 29/40

(52) U.S. Cl. CPC H01L 29/41775; H01L 29/401; H01L 29/66545; H01L 29/4236

(57) ABSTRACT

A power semiconductor device includes a semiconductor layer having a first conductivity type. An active region has a plurality of gate trenches. An interlayer dielectric (ILD) has a sloped region and a planar region. A metal contact hole has a sidewall aligned to the sloped region of the ILD. A metal contact is provided in the metal contact hole and couples the active region.

### BACKGROUND

The present disclosure relates to a power semiconductor device, in particular to a power device having a contact hole pattern formed on a sloped interlayer dielectric region to avoid a short between a gate and a source/drain.

Power semiconductor devices are used as a switch or rectifier in electrical devices and electronics. For example, low voltage MOSFETs with a breakdown voltage ranging from 12V to 30V are commonly used in motherboards, notebooks, portable appliances, and many other electronic devices. Since these electrical devices require power to operate, the power semiconductor devices need to be robust and reliable. Since power semiconductor devices would experience a failure if a gate-source short occurs, it would be desirable to prevent or minimize such a failure from occurring.

### SUMMARY

Embodiments of the present application relate to a power semiconductor device (e.g., MOSFET, IGBT, or the like) having gate trenches. In an embodiment, the power semiconductor device is configured for low voltage applications (e.g., 12V to 30 V).

In an embodiment, a power semiconductor device includes a semiconductor layer having a first conductivity type; an active region having a plurality of gate trenches; an interlayer dielectric (ILD) having a sloped region and a planar region; a metal contact hole having a sidewall aligned to the sloped region of the ILD; and a metal contact provided in the metal contact hole and coupling the active region.

In an embodiment, a layer underlying the ILD is configured to provide the ILD with the sloped region proximate to the active region. The underlying layer is a polysilicon pattern.

In an embodiment, the power device has a dummy region adjacent to the active region, and wherein an edge of the polysilicon pattern extends into the dummy region. The dummy region includes a plurality of dummy trenches and the polysilicon pattern extends over at least one of the dummy trenches.

In an embodiment, the ILD includes borophosphosilicate glass (BPSG). The polysilicon pattern has a thickness of at least about 500 nm, and the planar region of the ILD has a thickness of about 800 nm. A length of the sloped region is controlled using the thickness of the polysilicon pattern, a dopant concentration of the ILD, the thickness of the ILD, the ILD reflow condition, or a combination thereof.

In an embodiment, the metal contact hole has a bottom surface with a protruding portion. The protruding portion has a height of at least about 200 nm.

In an embodiment, the protruding portion is at least 10% of a depth of the metal contact hole and serves to compensate for a micro trench formed in the metal contact hole and reduce a potential for a short between the trench gate and the metal contact.

In an embodiment, the protruding portion is at least 20% of a depth of the metal contact hole, and the power device is a low voltage MOSFET, and the first conductivity type is an N-type conductivity.

In an embodiment, a polysilicon pattern has an edge that is no more than 1000 nm apart from the metal contact hole, the polysilicon pattern being provided below the ILD, wherein the protruding portion has a height of at least about 200 nm.

In another embodiment, a power semiconductor device includes a semiconductor layer having a first conductivity type; a trench region having an active region and a dummy region, the active region having a plurality of gate trenches, the dummy region having a plurality of dummy trenches; a polysilicon pattern provided over the semiconductor layer and having an edge extending into the dummy region and covering at least one dummy trench; an interlayer dielectric (ILD) provided over the polysilicon pattern and having a sloped region and a planar region, the sloped region being thicker than the planar region; a metal contact hole having a sidewall aligned to the sloped region of the ILD; and a metal contact provided in the metal contact hole and coupling the active region.

In an embodiment, the polysilicon pattern has a thickness of 500 nm to 600 nm, and the planar region of the ILD has a thickness of about at least 800 nm, and wherein the ILD includes borophosphosilicate glass (BPSG).

In an embodiment, the contact hole has a bottom surface with a protruding portion. The protruding portion has a height of at least about 200 nm and is at least about 20% of a depth of the metal contact hole, and wherein the power device is a low voltage MOSFET, and the first conductivity type is an N-type conductivity.

In yet another embodiment, a method for forming a power semiconductor device includes providing a semiconductor layer; etching the semiconductor layer to form a plurality of trenches, the trenches including gate trenches and dummy trenches, the gate trenches being provided in an active region and the dummy trenches being provided in a dummy region; depositing a polysilicon layer over the semiconductor layer, the polysilicon layer filling the gate trenches and the dummy trenches; patterning the polysilicon layer to form gate electrodes in the gate trenches and a polysilicon pattern having an edge no more than 1000 nm from the active region; forming an interlayer dielectric (ILD) over the pattern polysilicon, the ILD having a sloped region and a planar region, the sloped region being proximate the active region; forming a contact hole having a sidewall aligned to the sloped region of the ILD; and filling the contact hole with a metal layer.

In an embodiment, the polysilicon pattern covers at least one of the dummy trenches.

In an embodiment, the contact hole has a bottom surface having a protruding portion, the protruding portion having a height of at least 200 nm and being at least about 20% of a depth of the metal contact hole

### BRIEF DESCRIPTION OF THE DRAWINGS

FIG. 1 illustrates a power semiconductor device having a contact hole formed on a sloped ILD region according to an embodiment.

FIGS. 2-12 illustrate a method for forming a power semiconductor device having a contact hole formed on a sloped ILD region according to an embodiment.

### DETAILED DESCRIPTION

Embodiments of the present application relate to a power semiconductor device, e.g., a low voltage MOSFET, with a contact hole formed on a sloped interlayer dielectric (ILD) region. The sloped ILD region is thicker than a corresponding planar region and provides an additional material to compensate for any micro trench that might be formed during the contact hole etching process, which might otherwise cause a short between the gate and the source/drain. In an embodiment, the sloped ILD region is positioned at a location where a contact hole would be formed by utilizing the topography of an underlying layer, e.g., a gate polysilicon pattern.

In an embodiment, an edge (or a sidewall) of a source/drain contact hole is located on a sloped ILD region. The sloped ILD region is thicker than a planar region of the ILD layer and provides additional thickness to compensate for any micro trench that might be formed at or proximate to a sidewall of the contact hole during the contact hole etching process. The sloped ILD region is obtained by forming the ILD layer over an underlying layer that is patterned according to an implementation. In an embodiment, the underlying layer is patterned to have an edge proximate to a contact hole, where the edge is about 500 nm to 1000 nm from a sidewall of the contact hole. The patterned underlying layer may extend into a dummy trench region and cover at least one dummy trench. In an embodiment, the underlying layer is a gate polysilicon pattern.

In an embodiment, an edge of the sloped ILD region extends about 500 nm to about 1500 nm (e.g., about 750 nm) beyond an edge of the gate polysilicon pattern. In other embodiments, this distance may vary depending on the contact misalignment and the minimum ILD thickness requirements. In an embodiment, the minimum ILD thickness is at least twice that of the gate oxide thickness. In another embodiment, the minimum ILD thickness is at three times that of the gate oxide thickness. The gate oxide thickness may be about 20 nm for a 12V MOSFET and about 27 nm for a 24V MOSFET.

The length (or the angle) of the sloped ILD region 224 may be controlled using the thickness of the polysilicon pattern 218, a dopant concentration of the ILD material, the thickness of the ILD layer, and the ILD reflow condition.

A detailed description of embodiments is provided below along with accompanying figures. The scope of this disclosure is limited only by the claims and encompasses numerous alternatives, modifications, and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

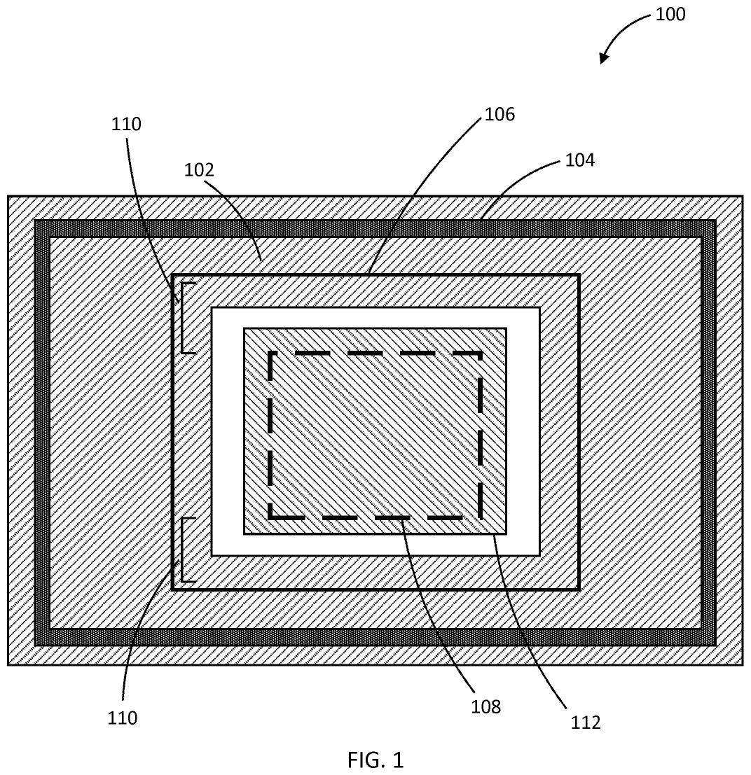

FIG. 1 illustrates a top view of a power semiconductor device 100 according to an embodiment of the present disclosure. As will be understood by one skilled in the art, certain layers have been removed for illustrative convenience. In an embodiment, the power device 100 is a low voltage metal oxide semiconductor field effect transistor (MOSFET), but the power device 100 may be other types of devices, e.g., high voltage MOSFETs or insulated gate bipolar transistors (IGBTs).

The power device 100 includes a polysilicon pattern 102 and a gate contact hole 104. The polysilicon pattern 102 is formed when the polysilicon is deposited in the gate trenches (not shown) and etched to form gate polysilicon. Accordingly, the polysilicon pattern 102 may be called a gate polysilicon pattern. The gate contact hole 104 is provided to form a metal contact (not shown) therein and electrically couple the gate polysilicon with the metal contact, so that voltages can be applied to the gate polysilicon to turn on or turn off the power device.

A trench region 106 having a plurality of trenches (not shown) is formed in the middle of the power device 100 in an implementation. In an embodiment, the trenches extend along a horizontal direction. The trench region 106 includes an active region 108 and a dummy region 110. The trenches in the active region are gate trenches that are electrically coupled to the metal contact and control the switching of the power device 100. The dummy region 110 is located at outer parts of the active region 108 and has a plurality of dummy trenches (not shown). The dummy trenches are typically not connected to the metal contact and are formed to provide structural uniformity to the gate trenches in the active region 108, so that the gate trenches formed at the outer part and the inner part of the active region 108 would have substantially the same gate characteristics.

A source/drain contact hole 112 is formed overlapping the active region 108 for a source/drain metal contact (not shown). In an embodiment, the area of the contact hole 112 extends beyond the active region 108 and has edges (or sidewalls) defined in the dummy region 110. The source/drain metal contact (or source/drain electrode) is insulated from the gate polysilicon using an interlayer dielectric (not shown). In an embodiment, the interlayer dielectric (ILD) is formed using borophosphosilicate glass. A sufficient amount of ILD material is needed between the gate polysilicon and the source/drain metal contact to prevent a short between the gate and the source/drain, which would result in a device failure.

However, a micro trench might be formed proximate to the edge of the contact hole during the contact hole etching process, making the contact hole deeper at or near the sidewall of the contact hole. This additional, unintended removal of the ILD makes the ILD thinner at that location and poses a potential danger for a gate-source/drain short. The sharp corner defined by the micro trench may also cause an electrical field concentration at that location when positive bias is applied to the gate polysilicon, which further increases the potential for the short.

In order to protect against the gate-source/drain short, the ILD layer is provided with a sloped ILD region that is suitably positioned and configured for a contact hole formation thereon. A contact hole etching is performed on the sloped ILD region, so that a sidewall of the contact hole is defined on the sloped ILD region. The sloped ILD region is thicker than a planar region of the ILD layer, and the additional ILD thickness of the sloped ILD region provides an extra margin for insulating the gate polysilicon and the metal contact. Accordingly, the additional thickness of the sloped ILD region may be used to compensate for a micro trench that might be formed during the contact etching process.

In an embodiment, the ILD layer is provided with a sloped ILD region by using a topography of an underlying layer. For example, the gate polysilicon pattern 102, which is provided below the ILD layer, is deposited to a suitable thickness and patterned to a suitable shape to position the sloped ILD region at a desired location with desired thickness and length. In an embodiment, the polysilicon pattern 102 has a thickness of about 400 nm to 800 nm (e.g., about 550 nm) and extends into the dummy region 112, so that the sloped ILD region can be position near the active region 108 and a sidewall of the contact hole can be formed on the sloped ILD region.

In an embodiment, an edge of the polysilicon pattern 102 facing the dummy region is about 500 nm to about 1000 nm from a sidewall of the contact hole 112 facing the edge of the polysilicon pattern 102. The slope (or the angle) of the sloping ILD region may be controlled by the ILD and reflow characteristics, as will be described later. With the contact hole aligned to the sloped ILD region, the power device 100 is less likely to experience a short between the gate and the source/drain, making the power device more robust and reliable.

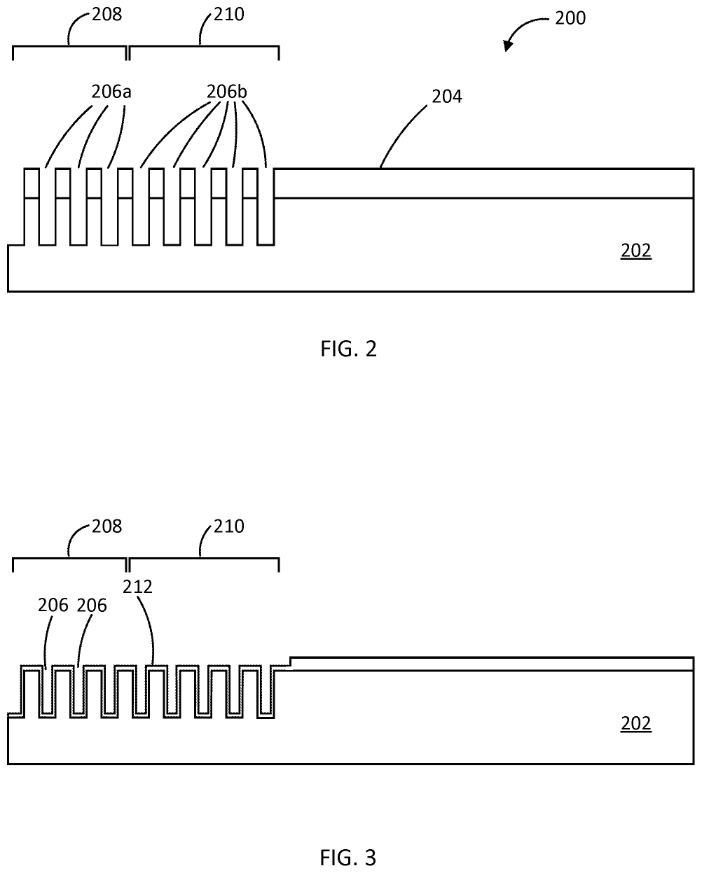

FIGS. 2-12 illustrate a method for forming a power semiconductor device 200 having a contact hole formed on a sloped ILD region to compensate for a micro trench profile according to an embodiment.

In FIG. 2, a semiconductor layer 202 is formed over a semiconductor substrate (not shown). In an embodiment, the substrate may be an N+ doped layer where the power device is a MOSFET. In another embodiment, the substrate may be a P+ layer where the power device is an IGBT. In an embodiment, the substrate is silicon, but it may be other semiconductor materials, such as a group IV semiconductor substrate, a group III-V compound semiconductor substrate, or a group II-VI oxide semiconductor substrate. For example, the group IV semiconductor substrate may include a silicon substrate, a germanium substrate, a silicon-germanium substrate, or silicon carbide substrate.

The semiconductor layer 202 may be made by growing a plurality of epi layers and implanting the N type impurities to convert the layer 202 to N type conductivity. The layer 202 is light doped with N type impurities to a dopant concentration of 1×10¹⁵ atoms/cm³ or less. Each epitaxial growth step forms an epi layer having about 2.5 to 3.2 microns. Annealing may be performed to facilitate the diffusion of the impurities.

A hard mask layer 204 is formed over the semiconductor layer 202 and patterned. In an embodiment, the hard mask layer is an oxide and has a thickness of about 3500 to 4000 Angstrom. The layer 202 is etched using the patterned hard mask layer 204 to form a plurality of trenches 206. In an embodiment, the trenches have a pitch of about 0.45 um and a depth of about 1 um.

The trenches 206 includes gate trenches 206a that are provided in an active region 208 and dummy trenches 206b that are provided a dummy region 210. The dummy trenches are formed in the dummy region in order to provide the gate trenches formed at the outer part of the active region with the substantially the same characteristics as those formed in the inner part of the active region.

Referring to FIG. 3, the hard mask layer 204 is removed and a gate dielectric layer 212 is formed conformally in the trenches 206. In an embodiment, the gate dielectric is a silicon oxide that is thermally grown over the layer 202. The gate dielectric thickness may be about 20 nm or more, e.g., about 30 nm.

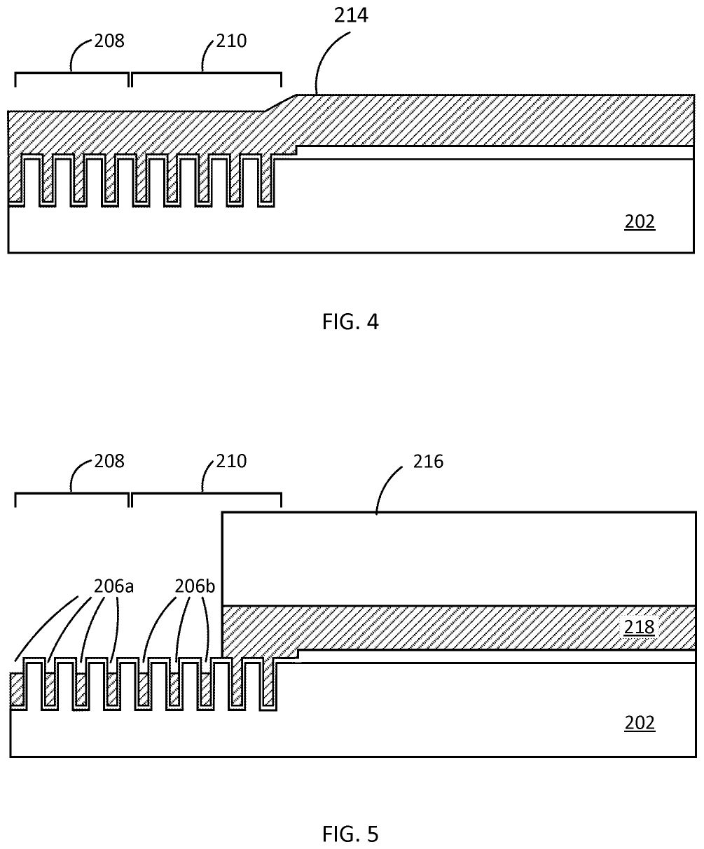

A conductive material (e.g., doped polysilicon) 214 is formed over the gate dielectric layer 212 (FIG. 4). In an embodiment, the polysilicon layer 214 has a thickness of about 400 nm to 800 nm (e.g., about 550 nm). A photoresist layer 216 is formed over the polysilicon layer 214 and patterned it (FIG. 5) to expose a selected portion of the polysilicon layer 214. The exposed polysilicon layer 214 is etched using the patterned photoresist. As a result, a portion of the polysilicon provided above the gate trenches 206a are removed, thereby forming gate polysilicon or gate electrodes. At this time, the polysilicon provided over a portion of the dummy trenches 206a are also removed.

In an embodiment, a remaining portion 218 of the polysilicon layer 214 extends into and partly covers the dummy region 210. This portion 218 remaining below the photoresist 216 extends partly into the dummy region from the outside of the trench region, so that a sloped ILD region can be formed proximate an active region of the power device and a contact hole can be formed on the sloped ILD region, as will be explained below. The portion 218 is referred herein as a “polysilicon pattern” or a “gate polysilicon pattern.” The polysilicon pattern 218 corresponds to the gate polysilicon pattern 102 illustrated in FIG. 1.

The polysilicon pattern 218 extending into a portion of the dummy region 210 provides an underlying topography that can be used to form a sloped ILD region, as will be described below. In an embodiment, the polysilicon pattern 218 has an edge that is about 500 nm to about 1000 nm apart from the active region 208. In an embodiment, the polysilicon pattern 218 has an edge that is about 750 nm or more apart from the active region 208. Although FIG. 5 illustrates the polysilicon pattern 218 extending into the dummy region 210, the edge of the polysilicon pattern 218 may not extend into the dummy region in other embodiments.

In an embodiment, a diode, such as a Zener diode (not shown), may be formed after the polysilicon deposition. The Zener diode is used to allow current to flow backwards when a reverse bias is applied.

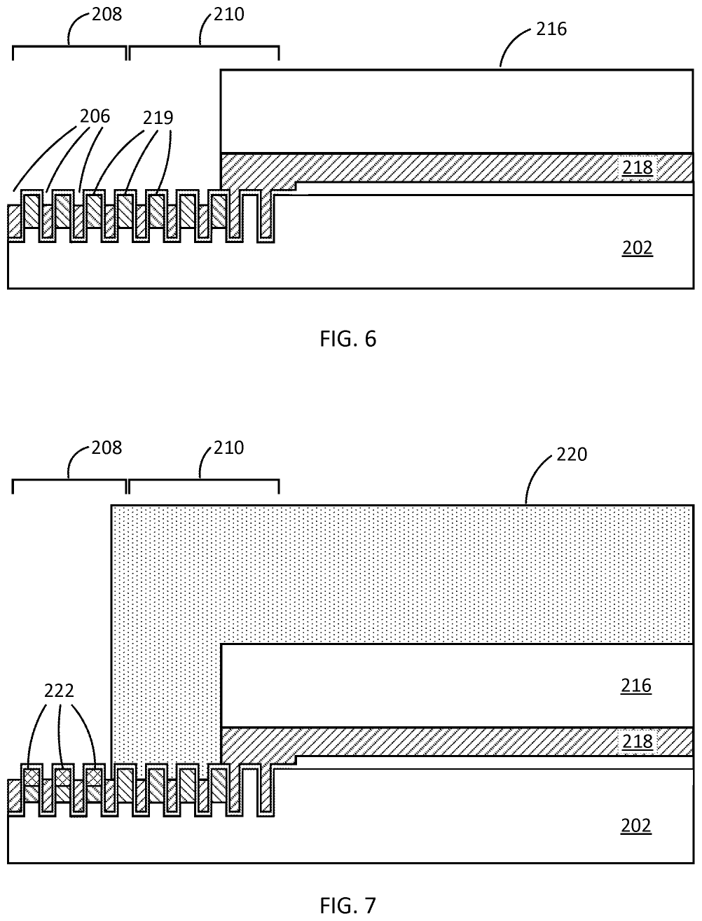

Referring to FIG. 6, an implantation process is performed to form a channel region 219. Ions having P-type conductivity are implanted on portions of the silicon layer 202 provided between the trenches 206. In an embodiment, boron ions are used for the implantation process. The implantation process may include multiple implantation steps. For example, boron ions are implanted three times using the following parameters: (1) implantation energy of 55 keV, dosage of 8×10¹² atoms/cm³, and implantation angle of 20 degrees, (2) implantation energy of 20 keV, dosage of 5×10¹³ atoms/cm³, and implantation angle of 20 degrees, and (3) implantation energy of 30 keV, dosage of 1.5×10¹⁴ atoms/cm³, and implantation angle of 55 degrees.

A photoresist layer 220 is formed and patterned to expose the active region 208 (FIG. 7). An implantation process is performed to form an N-type lightly doped region 222 in the active region 208. In an embodiment, arsenic ions are used to form the light doped region 222 using multiple steps. For example, arsenic ions are implanted into the silicon layer between the trenches 206a using the following parameters: (1) implantation energy of 75 keV, dosage of 1×10¹⁵ atoms/cm³, and implantation angle of 15 degrees, and (2) implantation energy of 30 keV, dosage of 1.5×10¹⁵ atoms/cm³, and implantation angle of 40 degrees. The ions are activated through annealing.

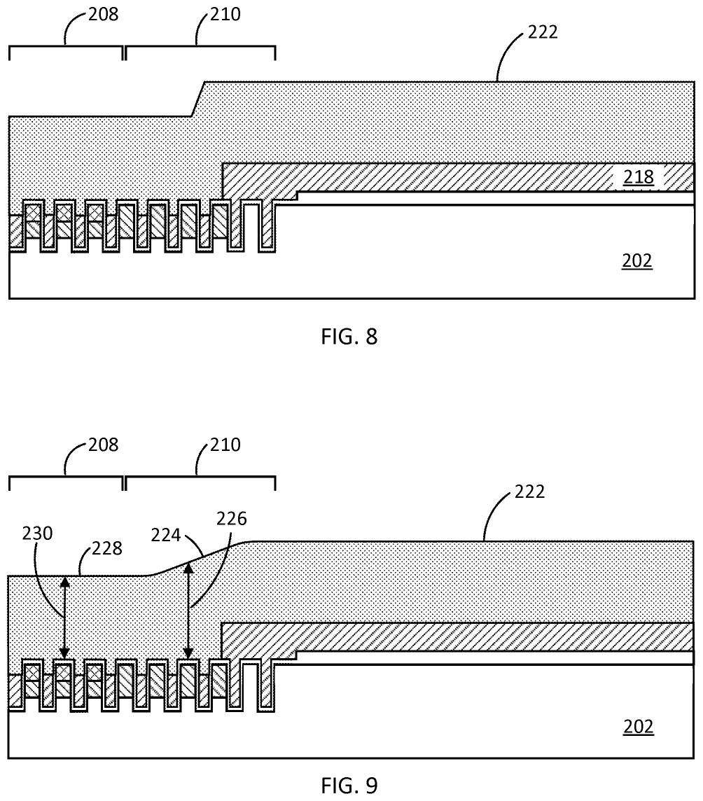

An ILD layer 222 is formed over the active region 208, the dummy region 210, and the polysilicon pattern 218 (FIG. 8). In an embodiment, the ILD layer is borophosphosilicate glass (BPSG) and formed to a thickness of about 600 nm to about 1000 nm (e.g., about 800 nm). The ILD layer may also include another layer, e.g., silicon oxide that is formed below the BPSG. The ILD layer 222 is provided to insulate the gate polysilicon from the metal contact to be formed subsequently.

Referring to FIG. 9, the ILD layer 222 is reflowed by annealing to fill the voids and provide good insulation between the gate and the metal contact (source/drain contact). Additionally, the reflow also provides the ILD layer 222 with a sloped region 224 with a thickness 226 and a planar region 228 with a thickness 230. The sloped region 224 is thicker than the planar region 228. In an embodiment, the thickness 226 of the sloped region 224 is about 1000 nm or more, and the thickness 230 of the planar region 228 is about 800.

In an embodiment, the sloped region 224 is at least 200 nm thicker than the planner region 228 (e.g., about 250 nm or more). The thickness 226 is defined to be about the thickness 230 plus a half the thickness of the polysilicon pattern 218. This additional ILD thickness at the sloped ILD region 224 is used to better insulate the gate and the source/drain metal contact.

In an embodiment, an edge of the sloped ILD region 224 extends about 500 nm to 1000 nm (e.g., about 750 nm) beyond an edge of the polysilicon pattern 218. In other embodiments, this distance may vary depending on the contact misalignment and the minimum ILD thickness requirement. The length (or the angle) of the sloped ILD region 224 may be controlled using the thickness of the polysilicon pattern 218, a dopant concentration of the ILD material, the thickness of the ILD layer, and the ILD reflow condition.

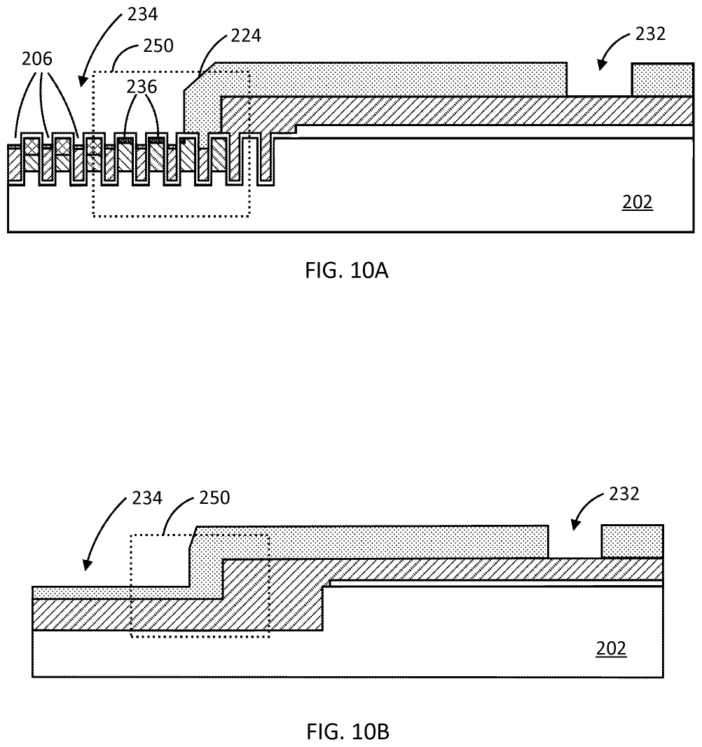

FIGS. 10A and 10B illustrate first and second contact holes 232 and 234 formed on the ILD layer 222 according to an embodiment. FIG. 10B is a cross-sectional view of FIG. 10A taken along an orthogonal direction of FIG. 10A. The first contact hole 232 defines a metal contact hole for the gate, and the second contact hole 234 defines a metal contact hole for the source/drain. A P+ region 236 is formed on the upper part of the silicon layer 202 and between the trenches 206. In an embodiment, the P+ region is formed by implanting boron ions using the following parameters: 1) implantation energy of 50 keV, dosage of 2×10¹⁵ atoms/cm³, and implantation angle of 7 degrees, and (2) implantation energy of 30 keV, dosage of 2×10¹⁵ atoms/cm³, and implantation angle of 7 degrees.

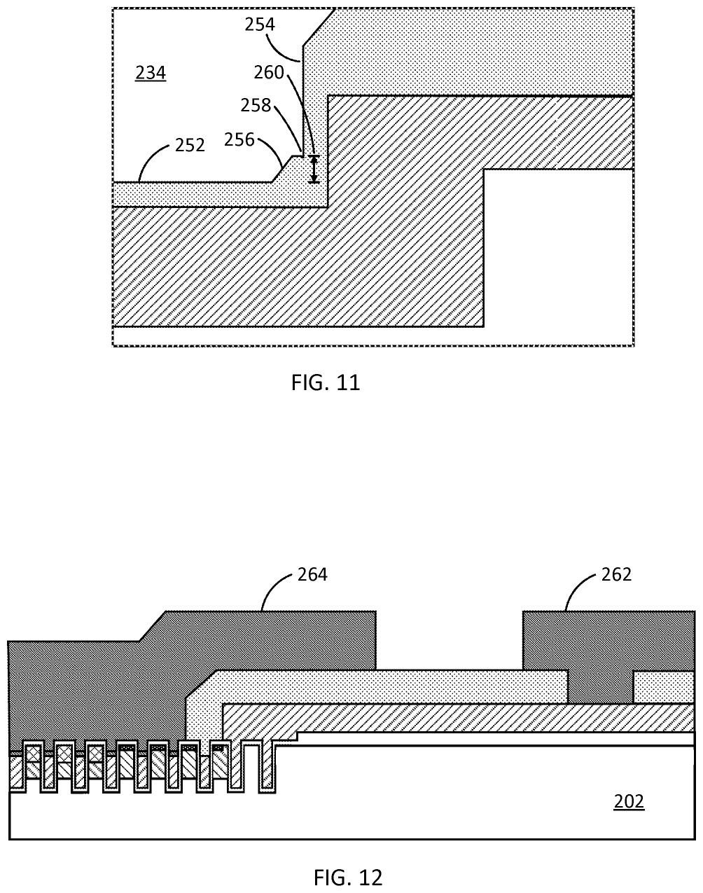

In an embodiment, the second contact hole 234 is defined to have a sidewall at the ILD sloped region 224. The additional thickness provided by the ILD sloped region 224 is used to compensate for any micro-trench profile that might result from the contact hole etching and prevent a short between the gate and the source/drain, as will be explained below using FIG. 11.

FIG. 11 is an enlarged view of an area 250 in FIG. 10B, illustrating a sidewall of the second contact hole 234. The second contact hole 234 has a bottom 252 and a sidewall 254. The sidewall 254 is defined on the sloped ILD region. The bottom 252 has an uneven profile with a protruding portion 256 at a bottom corner. In an embodiment, the protruding portion has a height 260 of about 200 nm or more (e.g., about 270 nm). The protruding region 256 results from etching the second contact hole 234 on the sloped ILD region that is thicker than the planar region of the ILD layer. The protruding region 256 is used to compensate for a micro trench 258 that might be formed at the corner during the contact hole etching process. The micro trench 258 may be about 10% of the contact hole depending on the contact hole etch process. For example, the micro trench 258 may be about 70 nm deep for a contact hole with a depth of about 700 nm.

In an embodiment, the sloped ILD region is formed by using a topography of an underlying layer. In an implementation, the underlying layer (e.g., the polysilicon pattern 218) extends into the dummy region. The underlying layer has a thickness of about 550 nm in an embodiment. Although the underlying layer is a polysilicon pattern in an embodiment, another layer may be used in other embodiments.

Referring to FIG. 12, a first metal is deposited into the first and second contact holes 232 and 234 to form first and second metal contacts 262 and 264. A second metal (not shown) may be deposited on the other side of the semiconductor layer 202. In an embodiment, the power device is a low voltage MOSFET that has a breakdown voltage of about 12V to 30 V. In other embodiments, the power device may be a high voltage MOSFET or IGBT. If the power device is an IGBT, it would have an additional P+ substrate or layer, as would be understood by one skilled in the art.

Aspects of the present disclosure have been described in conjunction with the specific embodiments thereof that are proposed as examples. Numerous alternatives, modifications, and variations to the embodiments as set forth herein may be made without departing from the scope of the claims set forth below. For example, the SJ power device of the present invention may be used in a low or medium voltage applications in addition to high voltage applications. Accordingly, embodiments as set forth herein are intended to be illustrative and not limiting.

1. A power semiconductor device, comprising:
a semiconductor layer having a first conductivity type;
an active region having a plurality of gate trenches;
an interlayer dielectric (ILD) having a sloped region and a planar region;
a metal contact hole extending beyond the active region and having a sidewall aligned to the sloped region of the ILD; and
a metal contact provided in the metal contact hole and coupling the active region.

2. The power semiconductor device of claim 1, further comprising:
a layer underlying the ILD being configured to provide the ILD with the sloped region proximate to the active region,
wherein the underlying layer is a polysilicon pattern.

3. (canceled)

4. The power semiconductor device of claim 2, wherein the power device has a dummy region adjacent to the active region,
wherein an edge of the polysilicon pattern extends into the dummy region, and
wherein the sidewall of the metal contact hole is disposed in the dummy region.

5. The power semiconductor device of claim 4, wherein the dummy region includes a plurality of dummy trenches and the polysilicon pattern extends over at least one of the dummy trenches.

6. The power semiconductor device of claim 4, wherein the ILD includes borophosphosilicate glass (BPSG).

7. The power semiconductor device of claim 6, wherein the polysilicon pattern has a thickness of at least about 500 nm, and the planar region of the ILD has a thickness of about 800 nm.

8. The power semiconductor device of claim 6, wherein a length of the sloped region is controlled using the thickness of the polysilicon pattern, a dopant concentration of the ILD, the thickness of the ILD, the ILD reflow condition, or a combination thereof.

9. The power semiconductor device of claim 1, wherein the metal contact hole has a bottom surface with a protruding portion.

10. The power semiconductor device of claim 9, wherein the protruding portion has a height of at least about 200 nm.

11. The power semiconductor device of 9, wherein the protruding portion is at least 10% of a depth of the metal contact hole and serves to compensate for a micro trench formed in the metal contact hole and reduce a potential for a short between the trench gate and the metal contact.

12. The power semiconductor device of claim 9, wherein the protruding portion is at least 20% of a depth of the metal contact hole, and
wherein the power device is a low voltage MOSFET, and the first conductivity type is an N-type conductivity.

13. The power semiconductor device of claim 12, further comprising:
a polysilicon pattern having an edge that is no more than 1000 nm apart from the metal contact hole, the polysilicon pattern being provided below the ILD,
wherein the protruding portion has a height of at least about 200 nm.

14. A power semiconductor device, comprising
a semiconductor layer having a first conductivity type;
a trench region having an active region and a dummy region, the active region having a plurality of gate trenches, the dummy region having a plurality of dummy trenches;
a polysilicon pattern provided over the semiconductor layer and having an edge extending into the dummy region and covering at least one dummy trench;
an interlayer dielectric (ILD) provided over the polysilicon pattern and having a sloped region and a planar region, the sloped region being thicker than the planar region;
a metal contact hole having a sidewall aligned to the sloped region of the ILD and a bottom surface with a protruding portion; and
a metal contact provided in the metal contact hole and coupling the active region.

15. The power semiconductor device of claim 14, wherein the polysilicon pattern has a thickness of 500 nm to 600 nm, and the planar region of the ILD has a thickness of about at least 800 nm, and
wherein the ILD includes borophosphosilicate glass (BPSG).

16. (canceled)

17. The power semiconductor device of claim 14, wherein the protruding portion has a height of at least about 200 nm and is at least about 20% of a depth of the metal contact hole, and
wherein the power device is a low voltage MOSFET, and the first conductivity type is an N-type conductivity.

18. A method for forming a power semiconductor device, the method comprising:
providing a semiconductor layer;
etching the semiconductor layer to form a plurality of trenches, the trenches including gate trenches and dummy trenches, the gate trenches being provided in an active region and the dummy trenches being provided in a dummy region;
depositing a polysilicon layer over the semiconductor layer, the polysilicon layer filling the gate trenches and the dummy trenches;
patterning the polysilicon layer to form gate electrodes in the gate trenches and a polysilicon pattern having an edge no more than 1000 nm from the active region;
forming an interlayer dielectric (ILD) over the pattern polysilicon, the ILD having a sloped region and a planar region, the sloped region being proximate the active region;
forming a contact hole having a sidewall aligned to the sloped region of the ILD; and
filling the contact hole with a metal layer.

19. The method of claim 18, wherein the polysilicon pattern covers at least one of the dummy trenches.

20. The method of claim 18, wherein the contact hole has a bottom surface having a protruding portion, the protruding portion having a height of at least 200 nm and being at least about 20% of a depth of the metal contact hole.

21. The power semiconductor device of claim 1, wherein the ILD is disposed over the semiconductor layer in a first direction, and the metal contact hole extends beyond the active region in a second direction, the second direction being orthogonal to the first direction.

22. The power semiconductor device of claim 1, wherein the power device has a dummy region adjacent to the active region, and the sidewall of the metal contact hole is disposed in the dummy region.
